(19) United States
(12) Patent Application Publication
(10) Pub. No.: US 2026/0323864 A1
(43) Pub. Date: Oct. 15, 2026

(54) THERMALLY MANAGING A TEMPERATURE SENSITIVE COMPONENT AND MECHANICALLY RETAINING INTERCONNECTED COMPONENTS USING A SHROUD

(71) Applicant: Dell Products L.P., Round Rock, TX (US)

(72) Inventors: BRENNAN TROY ROBERT SEAL, Austin, TX (US); JUSTIN TAYLOR FULWIDER, Round Rock, TX (US); RACHEL GABRIELLE MAZZINI, Dallas, TX (US); CHRIS EVERETT PETERSON, Austin, TX (US); ASHISH SHRIVASTAVA, Bangalore (IN); KHUSHWANT SINGH CHAUHAN, Sirohi (IN); SANDEEP SINGH, Robertsganj (IN); TSUNG-HSUN YANG, New Taipei City (TW)

(21) Appl. No.: 19/177,930

(22) Filed: Apr. 14, 2025

(51) Int. Cl. H05K 7/20

(52) U.S. Cl. CPC H05K 7/20145; H05K 7/20736

(57) ABSTRACT

Devices, systems, and methods for managing operation of a data processing system are disclosed. The data processing system may include a temperature sensitive component, a chassis that houses the temperature sensitive component, and a shroud. The shroud may be adapted to direct a portion of an airflow through the chassis toward the temperature sensitive component. The shroud may also be adapted to maintain a placement of at least one interconnecting component to prevent changes in rates of the portion of the airflow due to changes in position of the at least one interconnecting component. The at least one interconnecting component may be at least partially within the shroud, and may be at least partially positioned in the portion of the airflow.

### FIELD

Embodiments disclosed herein relate generally to data processing system management. More particularly, embodiments disclosed herein relate to systems and methods to thermally manage a temperature sensitive component of a data processing system.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a diagram illustrating a system in accordance with an embodiment.

FIG. 2A-2B shows a diagram illustrating a shroud in accordance with an embodiment.

FIG. 3 shows a diagram illustrating an airflow path through a chassis of a data processing system in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing operation of a data processing system. The data processing system may provide computer-implemented services.

To provide the computer-implemented services, the data processing system may include hardware components. The hardware components may have thermal dissipation requirements that must be met for the hardware components to operate nominally (e.g., with low probability of error, low chance of damage/failure, etc.). The thermal dissipation requirements may include, for example, an optimal temperature range, an optimal rate of airflow directed toward the hardware components to maintain the temperature range, and/or other requirements.

To meet the thermal dissipation requirements of the hardware components, the data processing system may use a liquid cooling system. For example, the liquid cooling system may be implemented using cooling tubes adapted to transport liquid coolant within a chassis of the data processing system. The liquid coolant may perform heat exchange with the hardware components to meet the thermal dissipation requirements.

However, thermal dissipation requirements for a portion of the hardware components (e.g., a temperature sensitive component such as an M.2 drive, a dual in-line memory module, etc.) of the data processing system may be unable to be met using the liquid system. To improve a likelihood of meeting the thermal dissipation requirements for the temperature sensitive component, an air cooling system may be used in addition to and/or in place of the liquid cooling system. The air cooling system may be implemented using a fan (and/or another system to circulate air through the data processing system). The fan may generate an airflow to cool the temperature sensitive component at prescribed rates. The airflow may be directed along an airflow path, the airflow path beginning at a first side of the data processing system and ending at a second side of the data processing system.

However, due to spatial constraints of the chassis of the data processing system, interconnecting components such as cooling tubes and/or cables may be positioned in the airflow path. As a result, a rate of a portion of the airflow directed toward the temperature sensitive component may be decreased, which may prevent adequate cooling of the temperature sensitive component. Additionally, a placement of the interconnecting components may change over time (e.g., due to various forces applied to the interconnecting components), which may reduce the likelihood that the thermal dissipation requirements for the temperature sensitive component are reliably met.

To improve the likelihood that the thermal dissipation requirements for the temperature sensitive component are reliably met, the data processing system may include a shroud. The shroud may be adapted to: (i) direct the portion of the airflow through the chassis toward the temperature sensitive component at a rate which meets the thermal dissipation requirements of the temperature sensitive component, and (ii) maintain a placement of at least one interconnecting component to prevent changes in rates of the portion of the airflow due to changes in position of the at least one interconnecting component.

To thermally manage the temperature sensitive component by directing the airflow, the shroud may be of a shape that is adapted to direct the portion of the airflow passing through the shroud toward the temperature sensitive component (e.g., thereby increasing heat dissipation of the temperature sensitive component). To maintain the placement of the at least one interconnecting component, the shroud may include at least one pair of holes that act as fixation elements for the at least one interconnecting component.

Thus, embodiments disclosed herein may provide an improved data processing system that may reliably meet thermal dissipation requirements of hardware components. To reliably meet the thermal dissipation requirements, the data processing system may include a shroud adapted to maintain a placement of interconnecting components of the data processing system so that the placement remains in a predictable position over time. The addition of the shroud to the data processing system may also result in improved airflow around the interconnecting components. Consequently, embodiments disclosed herein may address the technical problem of thermal operating condition limitations of data processing systems. By doing so, the thermal dissipation requirements of the hardware components may be met, and computer-implemented services may be provided by the data processing system as desired.

In an embodiment, a data processing system is provided. The data processing system may include: temperature sensitive component; chassis that houses the temperature sensitive component; and a shroud adapted to: direct a portion of an airflow through the chassis toward the temperature sensitive component; maintain a placement of at least one interconnecting component to prevent changes in rates of the portion of the airflow due to changes in position of the at least one interconnecting component, the at least one interconnecting component is: at least partially within the shroud, and at least partially positioned in the portion of the airflow.

The at least one interconnecting component may include at least one type of interconnecting component selected from a list consisting of: a cooling tube; and a cable.

The cooling tube may be adapted to transport liquid coolant within the chassis to thermally manage a portion of components of the data processing system.

The cable may be adapted to transport an electrical signal to at least a portion of components of the data processing system.

The shroud may include: a first portion including: an upper portion, and a lower portion; and a second portion including: at least one hole adapted to allow the at least one interconnecting component to traverse through the first portion.

The upper portion and the lower portion may be arranged to enclose an interior volume, and the at least one interconnecting component may be at least partially within the shroud by being positioned in a portion of the interior volume.

The upper portion and the lower portion may define an airflow path from a first side of the shroud to a second side of the shroud, the shroud may also include: an air inlet positioned with the first side to enable the portion of the airflow to enter the shroud, and an air exit positioned with the second side to enable the portion of the airflow to exit the shroud.

The airflow path may be through the interior volume, and the at least one interconnecting component may be at least partially positioned in the portion of the airflow by traversing the airflow path.

The portion of the airflow may exert a force on the at least one interconnecting component.

The force may be transmitted from the at least one interconnecting component to the shroud so that the at least one interconnecting component does not move in response to application of the force.

A shape of the upper portion and the lower portion may be adapted to cause a rate of the portion of the airflow at the second side of the shroud to be higher than a rate of the portion of the airflow at the first side of the shroud.

The rate of the portion of the airflow at the second side of the shroud may cause increased heat dissipation of the temperature sensitive component relative to the rate of the portion of the airflow at the first side of the shroud.

The shroud may include a pair of holes that act as fixation elements to maintain the placement of the at least one interconnecting component.

In an embodiment, a chassis for the data processing system is provided.

In an embodiment, a shroud for the chassis of the data processing system is provided.

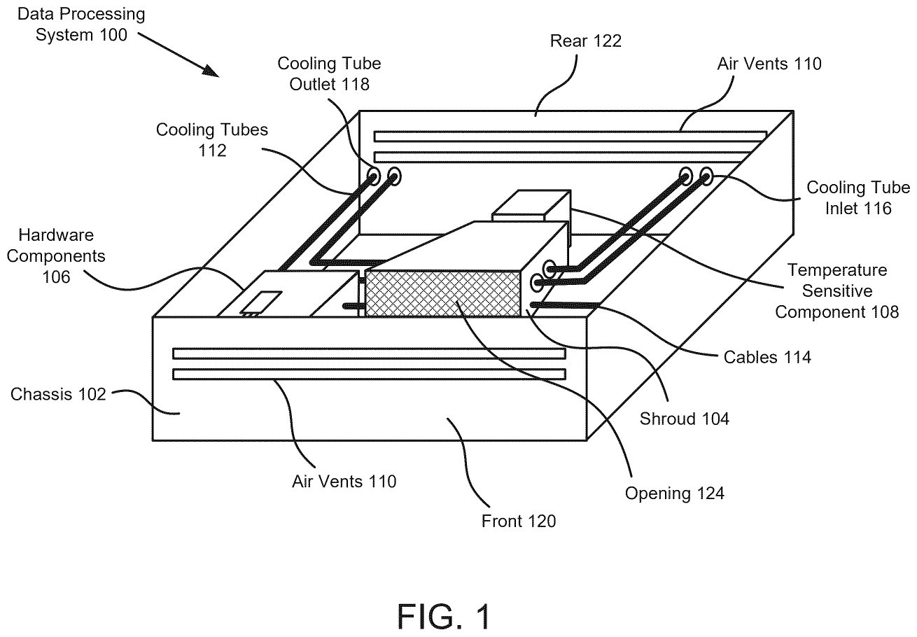

Turning to FIG. 1, a block diagram illustrating a system in accordance with an embodiment is shown. The system shown in FIG. 1 may provide any quantity and type of computer-implemented services. To provide the computer-implemented services, the system of FIG. 1 may include data processing system 100.

Data processing system 100 may include functionality to provide various types of computer-implemented services. The computer-implemented services may include any number and type of computer-implemented services. The computer-implemented services may include, for example, database services, data processing services, electronic communication services, and/or any other services that may be provided using one or more computing devices. Other types of computer-implemented services may be provided by data processing system 100 without departing from embodiments disclosed herein.

To provide the computer-implemented services, various components of data processing system 100 may be positioned inside of a chassis (e.g., chassis 102). Chassis 102 may be a physical enclosure for housing components of data processing system 100, such as hardware components 106. Hardware components 106 may include any type and quantity of hardware components such as processors, memory modules, storage devices, communications devices, and/or other types of devices. Hardware components 106 may also include power supplies, fans, and/or other types of devices usable to power and/or thermally manage the hardware components.

Any of hardware components 106 may be operably connected to one another using interconnecting components, such as cables 114. Cables 114 may include any type and quantity of cabling adapted to transport electrical signals and/or power to the various components of data processing system 100 (e.g., power cables, communication cables, fiber-optic cables, etc.). Cables 114 may enable hardware components 106 to perform their functionalities to facilitate provisioning of the computer-implemented services.

While performing their functionalities, hardware components 106 may generate and dissipate heat (e.g., into an airflow). However, hardware components 106 may have thermal dissipation requirements (e.g., a temperature range for operation). If operated at temperatures outside of these thermal dissipation requirements, hardware components 106 may not function as desired. Therefore, the computer-implemented services may not be reliably performed when the hardware components are too warm.

To improve a likelihood of meeting the thermal dissipation requirements for hardware components 106, the interconnecting components may also include cooling tubes 112. Cooling tubes 112 may include flexible and/or rigid tubing adapted to transport liquid coolant within chassis 102 to thermally manage a portion of the components of data processing system 100. For example, cooling tubes 112 may be a part of a liquid cooling system (e.g., a direct liquid cooling system) in which the liquid coolant is circulated through chassis 102. To do so, the liquid coolant may enter chassis 102 via cooling tube inlet 116 and may exit chassis 102 via cooling tube outlet 118. Cooling tube inlet 116 and cooling tube outlet 118 may include openings in chassis 102 adapted to allow cooling tubes 112 to be at least partially positioned within chassis 102. In doing so, the at least the portion of the components of data processing system 100 may be thermally managed.

However, thermal dissipation requirements for a portion of the hardware components of data processing system 100, such as temperature sensitive component 108, may be unable to be met using cooling tubes 112. Temperature sensitive component 108 may include any type and quantity of hardware components of data processing system 100 (e.g., an M.2 solid-state drive, a dual in-line memory module, etc.). The thermal dissipation requirements for temperature sensitive component 108 may be unable to be met using cooling tubes 112, for example, due to a size, shape, and/or position of temperature sensitive component 108 within chassis 102. For example, temperature sensitive component 108 may be positioned in chassis 102 in such a way that cooling tubes 112 are unable to dissipate sufficient heat generated by temperature sensitive component 108 to meet the thermal dissipation requirements.

To improve a likelihood of meeting the thermal dissipation requirements for temperature sensitive component 108, air cooling may be used (e.g., in addition to and/or in place of liquid cooling). To do so, as previously mentioned, hardware components 106 may include a fan (not shown) positioned in an interior of chassis 102. The fan may draw air from outside chassis 102 (e.g., cooler air) through air vents 110 (e.g., openings) positioned at a front side of chassis 102 (e.g., front 120). The air may perform thermal exchange with temperature sensitive component 108 (and/or hardware components 106) as they generate and dissipate heat. The fan may establish an airflow path through chassis 102. The airflow path may begin at a first side of chassis 102 (e.g., front 120) and may end at a second side of chassis 102 (e.g., rear 122). Intake air (e.g., cooler air) may enter chassis 102 through front 120, may travel along the airflow path, and may cool temperature sensitive component 108. Exhaust air (e.g., warmer air) may exit chassis 102 via air vents 110 positioned at rear 122.

Due to spatial constraints of chassis 102 (e.g., a size of chassis 102 may be limited by a size of a rack which houses chassis 102), the various components within chassis 102 (e.g., the interconnecting components) may be positioned in the airflow path. As a result, a rate of a portion of the airflow directed at temperature sensitive component 108 may be decreased, which may prevent adequate cooling of temperature sensitive component 108. To improve a likelihood of meeting the thermal dissipation requirements of temperature sensitive component 108, the rate of the portion of the airflow directed at temperature sensitive component 108 may be adjusted (e.g., via changing a power and/or position of a fan).

However, the interconnecting components (e.g., cabling 114 and/or cooling tubes 112) may not be fixed in place, and may move due to a force exerted by the airflow, movement of chassis 102, etc. Changes in positions of the interconnecting components may cause a change in rate of the airflow directed at temperature sensitive component 108, which may decrease a likelihood that the thermal dissipation requirements are met. Consequently, temperature sensitive component 108 may be unable to perform at least a portion of its functionality, which may negatively affect the quality and/or availability of the computer-implemented services provided by data processing system 100.

In general, embodiments disclosed herein may provide methods, systems, and/or devices for improving a likelihood that data processing system 100 is able to provide its computer-implemented services. To improve the likelihood that data processing system 100 is able to provide its computer-implemented services, data processing system 100 may include functionality to direct a portion of an airflow at a temperature sensitive hardware component internal to data processing system 100 and integral to the performance of the computer-implemented services (e.g., temperature sensitive component 108) at a rate which meets thermal dissipation requirements (e.g., through thermal exchange) of temperature sensitive component 108.

To do so, data processing system 100 may include shroud 104. Shroud 104 may be adapted to: (i) direct the portion of the airflow through chassis 102 toward temperature sensitive component 108 to thermally manage temperature sensitive component 108, and (ii) maintain a placement of at least one interconnecting component to prevent changes in rates of the portion of the airflow due to changes in position of the at least one interconnecting component.

To thermally manage temperature sensitive component 108 by directing the airflow, shroud 104 may include opening 124 (illustrated in FIG. 1 by a hatched infill). Opening 124 may include an opening through shroud 104 of any size and/or shape to allow the portion of the airflow to traverse through shroud 104. For example, opening 124 may be rectangular, circular, and/or any other shape. Shroud 104 may be of a shape that is adapted to direct the portion of the airflow passing through shroud 104 toward temperature sensitive component 108 (e.g., thereby increasing heat dissipation of temperature sensitive component 108). To maintain the placement of the at least one interconnecting component, shroud 104 may include at least one pair of holes that act as fixation elements for the at least one interconnecting component.

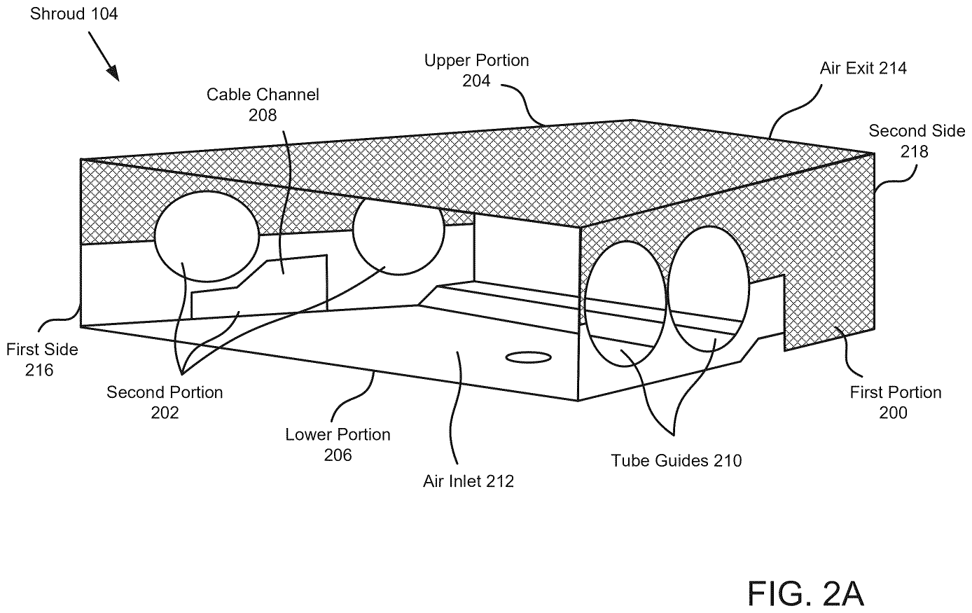

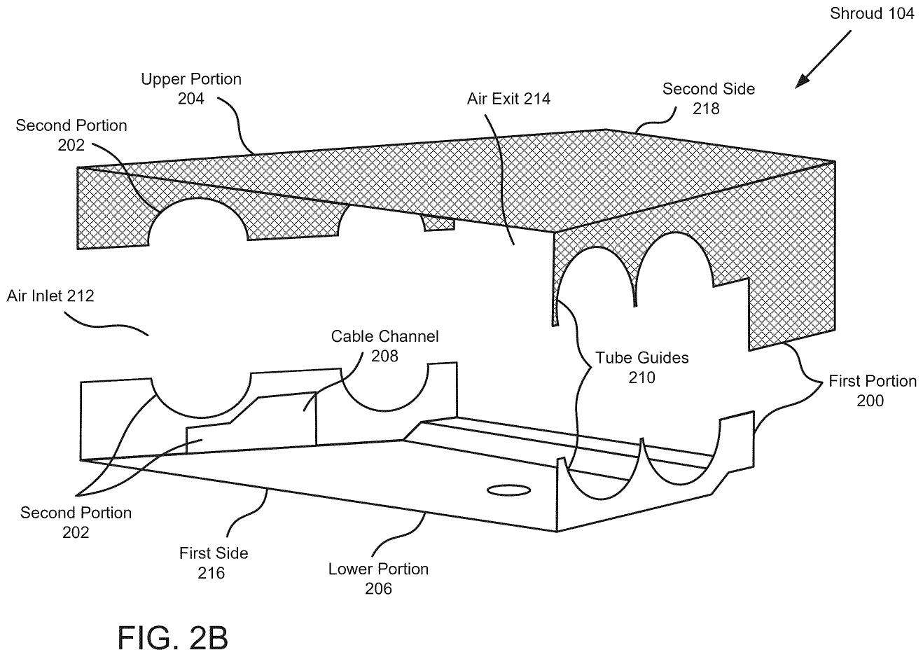

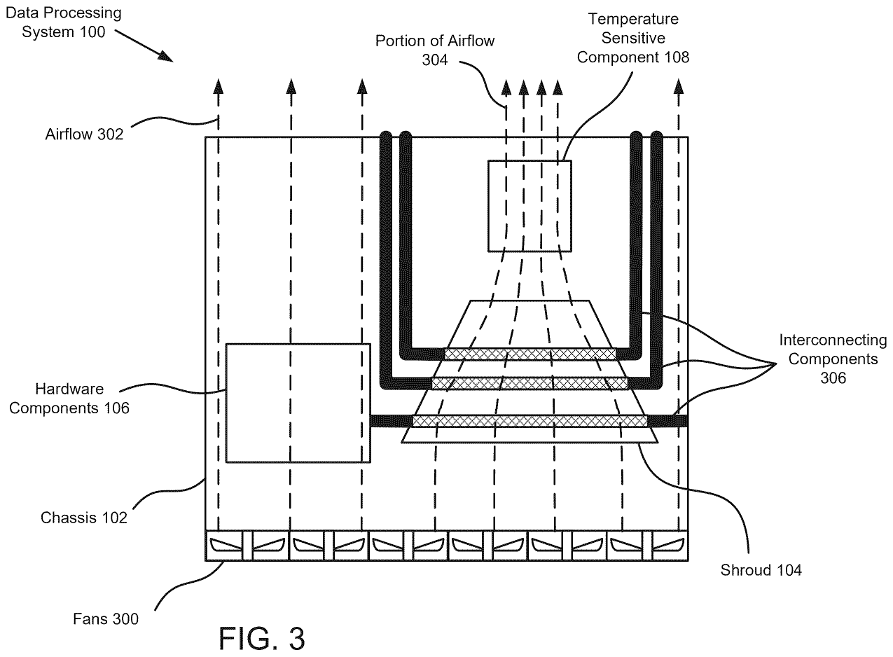

Therefore, shroud 104 may allow the thermal dissipation requirements for temperature sensitive component 108 to be met by allowing the portion of the airflow to be directed at temperature sensitive component 108 at a desired rate, even when interconnecting components are positioned at least partially within shroud 104 and/or in the portion of the airflow. Consequently, the computer-implemented services may be provided by data processing system 100 as desired. Refer to FIGS. 2A-2B for additional details regarding shroud 104. Refer to FIG. 3 for additional details regarding the airflow through chassis 102.

While illustrated in FIG. 1 with a limited number of specific components, a system may include additional, fewer, and/or different components without departing from embodiments disclosed herein. While described above with reference to an airflow path beginning at front 120 and ending at rear 122, the airflow path may travel in other directions and/or via other configurations without departing from embodiments disclosed herein.

Turning to FIGS. 2A-2B, diagrams illustrating a perspective view of a shroud (e.g., shroud 104) in accordance with an embodiment are shown. In FIG. 2A, shroud 104 may be illustrated as a unitary component, and in FIG. 2B shroud 104 may be illustrated in a partially exploded view. As discussed above, shroud 104 may be used to thermally manage a temperature sensitive component of a data processing system. To thermally manage the temperature sensitive component, shroud 104 may: (i) direct a portion of an airflow through a chassis of the data processing system toward the temperature sensitive component, and (ii) maintain a placement of at least one interconnecting component. By doing so, a rate of the portion of the airflow may reliably meet thermal dissipation requirements of the temperature sensitive component required to perform the computer-implemented services.

To direct the portion of the airflow, shroud 104 may include first portion 200. First portion 200 may be any shape and/or dimension required to fit within a predetermined space within the chassis (e.g., chassis 102). For example, the predetermined space may be positioned with respect to the temperature sensitive component so that shroud 104 directs the portion of the airflow toward the temperature sensitive component. Refer to the description of FIG. 3 for additional details regarding the portion of the airflow.

First portion 200 may include: (i) upper portion 204, and (ii) lower portion 206. Upper portion 204 and lower portion 206 may be implemented with a shell, walls, and/or other structures that may be arranged to enclose an interior volume. Lower portion 206 may include, for example, a base portion and two partial wall portions. Upper portion 204 may include, for example, a top portion and two partial wall portions. Upper portion 204 may securely attach to lower portion 206 to enclose the interior volume.

Upper portion 204 and lower portion 206 may define an airflow path from a first side of shroud 104 (e.g., first side 216) to a second side of shroud 104 (e.g., second side 218). First side 216 may include a portion of shroud 104 positioned facing a source of the airflow (e.g., a fan, vent, and/or other source of airflow, refer to FIG. 3). Second side 218 may include a portion of shroud 104 positioned facing the temperature sensitive component.

Air inlet 212 may be positioned with first side 216 to enable a portion of the airflow to enter shroud 104. Air inlet 212 may include an opening in first side 216 of any size and/or shape through which the portion of the airflow may enter shroud 104. For example, air inlet 212 may be rectangular, circular, and/or any other shape.

Air exit 214 may be positioned with second side 218 to enable the portion of the airflow to exit shroud 104. Air exit 214 may include an opening in second side 218 of any size and/or shape through which the portion of the airflow may exit shroud 104. For example, air exit 214 may be rectangular, circular, and/or any other shape.

A shape of upper portion 204 and lower portion 206 may be adapted to direct the portion of the airflow from first side 216 through second side 218. Thus, as second side 218 may be positioned facing the temperature sensitive component, shroud 104 may be adapted to direct the portion of the airflow toward the temperature sensitive component.

The shape of upper portion 204 and lower portion 206 may also be adapted to impact a rate of airflow through shroud 104. For example, the shape may be adapted to cause a rate of the portion of the airflow at second side 218 to be higher than a rate of the portion of the airflow at first side 216 (e.g., air exiting shroud 104 may travel at a higher velocity than air entering shroud 104). For example, the shape of upper portion 204 and lower portion 206 may result in a size of air inlet 212 being larger than a size of air exit 214 (e.g., a top and base portion may be trapezoidal). As a result of the difference in size, an air channeling effect may occur, which may result in an increase in the rate of the portion of the airflow as the portion of the airflow traverses shroud 104. Refer to the description of FIG. 3 for additional details regarding the rate of the portion of the airflow.

While described with respect to the shape of upper portion 204 and lower portion 206 being adapted to increase the rate of the portion of the airflow through shroud 104 while the portion of the airflow is being directed toward the temperature sensitive component, it will be appreciated that the rate of the portion of the airflow may decrease or remain the same without departing from embodiments disclosed herein.

Shroud 104 may also include second portion 202 to maintain the placement of the at least one interconnecting component. For example, the at least one interconnecting component may include cooling tubes, cables, and/or any other type of interconnecting component (refer to the description of FIG. 1 for additional details). Second portion 202 may include at least one hole adapted to allow the at least one interconnecting component to traverse through first portion 200. Second portion 202 include, for example, any number of openings and/or ports of any size and shape through an exterior surface of upper portion 204 and/or lower portion 206. The at least one hole may allow the at least one interconnecting component to enter and/or exit shroud 104. Consequently, the at least one interconnecting component may be positioned at least partially within a portion of the interior volume of shroud 104.

For example, second portion 202 may include cable channel 208 and/or tube guides 210. Cable channel 208 may include an opening adapted to allow any type and quantity of cables to traverse through the first portion. Tube guides 210 may include openings adapted to allow any type and quantity of cooling tubes to traverse through the first portion. Tube guides 210 may include semicircular holes through upper portion 204 and lower portion 206. It will be appreciated that cable channel 208 and/or tube guides 210 may be implemented using holes of any size, shape, and/or quantity without departing from embodiments disclosed herein.

Second portion 202 may allow the at least one interconnecting component to traverse through first portion 200, and may act as fixation elements to maintain the placement of the at least one interconnecting component. For example, second portion 202 may include a pair of holes in first portion 200 to allow a cooling tube to enter and exit the interior portion of shroud 104. The pair of holes may be of a size and/or shape adapted to enclose the cooling tube in a manner which secures the cooling tube in place. As a result, the cooling tube may remain in a desired position and/or orientation, even if a force is applied to the cooling tube, the data processing system is moved, etc.

While illustrated in FIGS. 2A-2B with example shapes, it will be appreciated that components of a shroud in accordance with embodiments disclosed herein may have different and/or more complicated shapes (e.g., curved, multifaceted, etc.) without departing from embodiments disclosed herein.

While illustrated in FIGS. 2A-2B with a limited number of specific components, a shroud may include additional, fewer, and/or different components without departing from embodiments disclosed herein.

The shroud may allow for a desired rate of airflow to be directed at a temperature sensitive component of data processing system 100 and, therefore, may increase a likelihood of the temperature sensitive component meeting thermal dissipation requirements. Turning to FIG. 3, a block diagram illustrating an airflow path through a chassis (e.g., chassis 102) of data processing system 100 is shown.

As discussed above, data processing system 100 may include hardware components, such as hardware components 106 and temperature sensitive component 108, which may be integral to the performance of computer-implemented services by data processing system 100. Hardware components 106 and temperature sensitive component 108 may be associated with thermal dissipation requirements, and meeting the thermal dissipation requirements may enable hardware components 106 and temperature sensitive component 108 to operate in a desired manner.

To meet the thermal dissipation requirements of the various components of data processing system 100, data processing system 100 may include capabilities to dissipate heat generated by the various components via: (i) a liquid cooling system (e.g., implemented using cooling tubes), and/or (ii) an air cooling system.

To implement the air cooling system, data processing system 100 may include fans 300. Fans 300 may initiate an airflow (e.g., airflow 302) throughout data processing system 100. Fans 300 may include any number of fans and may establish an airflow path for airflow 302 from a first side of data processing system 100 to a second side of data processing system 100. For example, fans 300 may draw cooler air through air vents in the first side (not shown) and may exhaust warmer air though air vents in the second side.

While shown in FIG. 3 with example airflows, the airflows may follow different paths, may be in different directions (e.g., reversed), and/or may have different characteristics without departing from embodiments disclosed herein. While shown in FIG. 3 with fans 300 positioned in the interior of chassis 102, it will be appreciated that fans 300 may be positioned exterior to chassis 102 (e.g., airflow 302 may then enter chassis 102 through air vents in chassis 102) without departing from embodiments disclosed herein.

The thermal dissipation requirements for hardware components 106 may differ from the thermal dissipation requirements for temperature sensitive component 108. For example, the thermal dissipation requirements may specify an optimal rate of airflow to efficiently perform thermal exchange and cool the various components. The optimal rate of airflow for hardware components 106 may be generated by fans 300 (e.g., the optimal rate may be the rate of airflow 302).

However, fans 300 may be incapable of generating the optimal rate of airflow for temperature sensitive component 108 (e.g., increasing the size and/or power of fans 300 in order to increase the rate of airflow generated by fans 300 may be impractical due to the spatial limitations of data processing system 100, generation of an undesirable amount of static discharge within data processing system 100, etc.). Fans 300 may also fail to meet the thermal dissipation requirements of temperature sensitive component 108 due to a positioning of temperature sensitive component 108 within chassis 102. For example, other components of data processing system 100 (not shown) may at least partially block airflow 302 from reaching temperature sensitive component 108 at the optimal rate to meet the thermal dissipation requirements of temperature sensitive component 108. Thus, airflow 302 generated by fans 300 may not meet the thermal dissipation requirements of temperature sensitive component 108.

In a first example, hardware components 106 may include a processor. To meet the thermal dissipation requirements for the processor, the processor may be cooled via a combination of liquid cooling (e.g., the processor may be positioned proximate to cooling tubes within chassis 102) and air cooling. Because a portion of the heat generated by the processor may be dissipated via liquid cooling, the optimal rate of airflow specified by the thermal dissipation requirements for the processor may be the rate of airflow 302 generated by fans 300.

In a second example, temperature sensitive component 108 may include an M.2 drive. Due to the positioning of the M.2 drive within chassis 102, the M.2 drive may be unable to be cooled via liquid cooling and/or may be positioned in a manner in which airflow 302 is unable to sufficiently cool the M.2 drive (e.g., the M.2 drive may be partially blocked by other components of data processing system 100). Thus, fans 300 may be incapable of meeting the thermal dissipation requirements for the M.2 drive.

To meet the thermal dissipation requirements of temperature sensitive component 108, data processing system 100 may include, as discussed, shroud 104. Shroud 104 may meet the thermal dissipation requirements of temperature sensitive component 108 by directing a portion of airflow 302 (e.g., portion of airflow 304) toward temperature sensitive component 108. The rate of portion of airflow 304 may be higher, lower, or the same as the rate of airflow 302.

For example, due to a shape of shroud 104, the rate of portion of airflow 304 may be higher than the rate of airflow 302 (e.g., a rate of portion of airflow 304 may be higher when exiting a second side of shroud 104 than a rate of portion of airflow 304 entering at a first side of shroud 104). The shape of shroud 104 may therefore be adapted to cause the rate of portion of airflow 304 to be higher than the rate of airflow 302 by generating an air channeling effect (e.g., shroud 104 may guide portion of airflow 304 towards temperature sensitive component 108). Refer to the description of FIGS. 2A-2B for additional details regarding shroud 104.

For example, fans 300 may generate airflow 302 having a rate of 1425 linear feet per minute (LFM). Portion of airflow 304 may, therefore, have a rate of 1425 LFM when entering the first side of shroud 104. Upon exiting the second side of shroud 104, portion of airflow 304 may have a rate of 2085 LFM. The higher rate of portion of airflow 304 may cause increased heat dissipation via thermal exchange of temperature sensitive component 108 relative to the lower rate of airflow 302. For example, during operation, a temperature of temperature sensitive component 108 without shroud 104 may be 45.7 °C, and the temperature of temperature sensitive component 108 with shroud 104 may be 45.4 °C. Thus, shroud 104 may improve a likelihood of meeting the thermal dissipation requirements of temperature sensitive component 108.

As discussed above, data processing system 100 may include interconnecting components 306. Interconnecting components 306 may include at least one interconnecting component, such as cooling tubes, cables, and/or other types of components required for data processing system 100 to provide the computer-implemented services as desired. Interconnecting components 306 may be at least partially positioned in portion of airflow 304 by traversing the airflow path of portion of airflow 304.

For example, the airflow path of portion of airflow 304 may be through an interior volume of shroud 104. Due to spatial limitations of data processing system 100, interconnecting components 306 may be positioned at least partially within the interior volume of shroud 104 (portions of interconnecting components 306 are illustrated with a hatched infill in FIG. 3 to indicate the portions are positioned within the interior volume of shroud 104). Consequently, interconnecting components 306 may be at least partially positioned in portion of airflow 304.

Because interconnecting components 306 may be at least partially positioned in portion of airflow 304, portion of airflow 304 may exert a force (e.g., air pressure) on interconnecting components 306. Other forces may also be exerted on interconnecting components 306, such as applied force, which may be exerted on interconnecting components 306 by moving all or a portion of data processing system 100.

While the force is exerted on interconnecting components 306, a placement of interconnecting components 306 may be maintained. For example, the placement may be maintained by transmitting the force from interconnecting components 306 to shroud 104 so that interconnecting components 306 do not move in response to the application of the force. The force may be transmitted to shroud 104 due to interconnecting components being in direct contact and secured in place by shroud 104. For example, shroud 104 may include fixation elements (e.g., a pair of holes, etc.) to secure the placement of interconnecting components 306. The fixation elements may enable the transmission of the force so that interconnecting components 306 do not move. Refer to the description of FIGS. 2A-2B for additional details regarding maintaining the placement of interconnecting components.

Because the placement of interconnecting components 306 may be maintained, the thermal dissipation requirements of temperature sensitive component 108 may be reliably met. Consider a scenario in which a shroud directed portion of airflow 304 toward temperature sensitive component 108 but did not maintain the placement of interconnecting components 306. In this example, the optimal rate of airflow of portion of airflow 304 may be generated using the shroud. However, if the placement of interconnecting components were to change (e.g., due to moving data processing system 100, due to moving a component of data processing system 100), the rate of airflow of portion of airflow 304 may also change. Therefore, in this example, the optimal rate of airflow of portion of airflow 304 may be unable to be reliably maintained, and temperature sensitive component 108 may not operate as desired.

Thus, by integrating shroud 104 having capabilities to direct portion of airflow 304 toward temperature sensitive component 108 and maintain the placement of interconnecting components 306 into data processing system 100, a likelihood of reliably meeting the thermal dissipation requirements of temperature sensitive component 108 may be improved. As a result, the computer-implemented services provided by data processing system 100 using temperature sensitive component 108 may be provided as desired.

Accordingly, embodiments disclosed herein may address, among others, the technical problem of thermal management of hardware components that may generate heat during operation. Embodiments disclosed herein may do so by directing a portion of an airflow toward a temperature sensitive component while maintaining a placement of at least one interconnecting component of the data processing system. Thus, a data processing system in accordance with embodiments may allow for reliable rates of cooling the temperature sensitive component while conforming to computing environment standards that may limit spatial availability within a chassis of a data processing system.

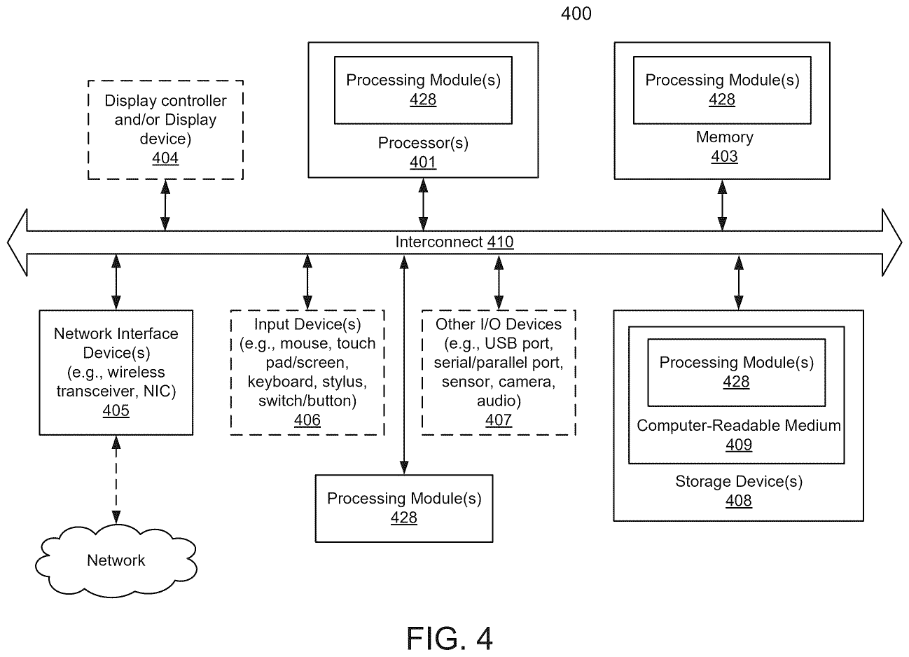

Any of the components illustrated in FIGS. 1-3 may be implemented with one or more computing devices. Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system. Note also that system 400 is intended to show a high level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401 may communicate with memory 403, which in one embodiment can be implemented via multiple memory devices to provide for a given amount of system memory. Memory 403 may include one or more volatile storage (or memory) devices such as random access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system, comprising:
temperature sensitive component;
chassis that houses the temperature sensitive component; and
a shroud adapted to:
direct a portion of an airflow through the chassis toward the temperature sensitive component to thermally manage the temperature sensitive component;
maintain a placement of at least one interconnecting component to prevent changes in rates of the portion of the airflow due to changes in position of the at least one interconnecting component, the at least one interconnecting component is:
at least partially within the shroud, and
at least partially positioned in the portion of the airflow.

2. The data processing system of claim 1, wherein the at least one interconnecting component comprises at least one type of interconnecting component selected from a list consisting of:
a cooling tube; and
a cable.

3. The data processing system of claim 2, wherein the cooling tube is adapted to transport liquid coolant within the chassis to thermally manage a portion of components of the data processing system.

4. The data processing system of claim 2, wherein the cable is adapted to transport an electrical signal to at least a portion of components of the data processing system.

5. The data processing system of claim 1, wherein the shroud comprises:
a first portion comprising:
an upper portion, and
a lower portion; and
a second portion comprising:
at least one hole adapted to allow the at least one interconnecting component to traverse through the first portion.

6. The data processing system of claim 5, wherein the upper portion and the lower portion are arranged to enclose an interior volume, and the at least one interconnecting component is at least partially within the shroud by being positioned in a portion of the interior volume.

7. The data processing system of claim 6, wherein the upper portion and the lower portion define an airflow path from a first side of the shroud to a second side of the shroud, the shroud further comprising:
an air inlet positioned with the first side to enable the portion of the airflow to enter the shroud, and
an air exit positioned with the second side to enable the portion of the airflow to exit the shroud.

8. The data processing system of claim 7, wherein the airflow path is through the interior volume, and the at least one interconnecting component is at least partially positioned in the portion of the airflow by traversing the airflow path.

9. The data processing system of claim 8, wherein the portion of the airflow exerts a force on the at least one interconnecting component.

10. The data processing system of claim 9, wherein the force is transmitted from the at least one interconnecting component to the shroud so that the at least one interconnecting component does not move in response to application of the force.

11. The data processing system of claim 7, wherein a shape of the upper portion and the lower portion is adapted to cause a rate of the portion of the airflow at the second side of the shroud to be higher than a rate of the portion of the airflow at the first side of the shroud.

12. The data processing system of claim 11, wherein the rate of the portion of the airflow at the second side of the shroud causes increased heat dissipation of the temperature sensitive component relative to the rate of the portion of the airflow at the first side of the shroud.

13. The data processing system of claim 1, wherein the shroud comprises a pair of holes that act as fixation elements to maintain the placement of the at least one interconnecting component.

14. A chassis for a data processing system, the chassis comprising:
temperature sensitive component; and
a shroud adapted to:
direct a portion of an airflow through the chassis toward the temperature sensitive component to thermally manage the temperature sensitive component;
maintain a placement of at least one interconnecting component to prevent changes in rates of the portion of the airflow due to changes in position of the at least one interconnecting component, the at least one interconnecting component is:
at least partially within the shroud, and
at least partially positioned in the portion of the airflow.

15. The chassis of claim 14, wherein the shroud comprises a pair of holes that act as fixation elements to maintain the placement of the at least one interconnecting component.

16. The chassis of claim 14, wherein the shroud comprises:
a first portion comprising:
an upper portion, and
a lower portion; and
a second portion comprising:
at least one hole adapted to allow the at least one interconnecting component to traverse through the first portion.

17. The chassis of claim 16, wherein the upper portion and the lower portion are arranged to enclose an interior volume, and the at least one interconnecting component is at least partially within the shroud by being positioned in a portion of the interior volume.

18. A shroud for a chassis of a data processing system, the shroud comprising:
a first portion adapted to direct a portion of an airflow through the chassis toward a temperature sensitive component positioned in the chassis to thermally manage the temperature sensitive component; and
a second portion adapted to maintain a placement of at least one interconnecting component positioned in the chassis to prevent changes in rates of the portion of the airflow due to changes in position of the at least one interconnecting component, the at least one interconnecting component is:
at least partially within the shroud, and
at least partially positioned in the portion of the airflow.

19. The shroud of claim 18, wherein the shroud comprises a pair of holes that act as fixation elements to maintain the placement of the at least one interconnecting component.

20. The shroud of claim 18, wherein the at least one interconnecting component comprises at least one type of interconnecting component selected from a list consisting of:
a cooling tube; and
a cable.
